(19) United States
(12) Patent Application Publication
(10) Pub. No.: US 2024/0090221 A1
(43) Pub. Date: Mar. 14, 2024

(54) MEMORY DEVICE

(71) Applicant: Kioxia Corporation, Tokyo (JP)

(72) Inventor: Yoichi MINEMURA, Yokkaichi Mie (JP)

(21) Appl. No.: 18/459,697

(22) Filed: Sep. 1, 2023

(30) Foreign Application Priority Data
Sep. 14, 2022 (JP) 2022-146416

(51) Int. Cl. H10B 43/27

(52) U.S. Cl. CPC H10B 43/27; H10B 43/10

(57) ABSTRACT

A memory device includes: insulator layers spaced apart from one another in a first direction; conductor layers spaced apart from one another in the first direction, the insulator layers and the insulator layers alternately arranged along the first direction; and a memory pillar extending in the first direction to intersect the conductor layers. The conductor layers include a first conductor layer having a first portion and a second portion in contact with the memory pillar. The first portion is recessed relative to the second portion in a second direction intersecting the first direction.

### CROSS-REFERENCE TO RELATED APPLICATION

This application is based upon and claims the benefit of priority from Japanese Patent Application No. 2022-146416, filed Sep. 14, 2022, the entire contents of which are incorporated herein by reference.

### FIELD

Embodiments described herein relate generally to a memory device.

### BACKGROUND

A NAND flash memory is known as a memory device that can store data in a non-volatile manner. The memory device such as this NAND flash memory employs a three-dimensional memory structure for high integration and large capacity.

### DESCRIPTION OF THE DRAWINGS

FIG. 1 is a block diagram illustrating a configuration of a memory system including a memory device according to an embodiment.

FIG. 2 is a circuit diagram illustrating an example of a circuit configuration of a memory cell array in the memory device according to the embodiment.

FIG. 3 is a plan view illustrating an example of a planar layout of the memory cell array in the memory device according to the embodiment.

FIG. 4 is a plan view illustrating an example of a detailed planar layout in a memory area of the memory device according to the embodiment.

FIG. 5 is a cross-sectional view taken along line V-V in FIG. 4, illustrating an example of a cross-sectional structure in the memory area of the memory device according to the embodiment.

FIG. 6 is a cross-sectional view taken along line VI-VI in FIG. 5, illustrating an example of a cross-sectional structure of a memory pillar in the memory device according to the embodiment.

FIG. 7 is a cross-sectional view of an area VII in FIG. 5, illustrating an example of the cross-sectional structure in the memory area of the memory device according to the embodiment.

FIG. 8 is a cross-sectional view illustrating an example of a cross-sectional structure of the memory device according to the embodiment during manufacturing.

FIG. 9 is a cross-sectional view illustrating an example of the cross-sectional structure of the memory device according to the embodiment during manufacturing.

FIG. 10 is a cross-sectional view illustrating an example of the cross-sectional structure of the memory device according to the embodiment during manufacturing.

FIG. 11 is a cross-sectional view illustrating an example of the cross-sectional structure of the memory device according to the embodiment during manufacturing.

FIG. 12 is a cross-sectional view illustrating an example of the cross-sectional structure of the memory device according to the embodiment during manufacturing.

FIG. 13 is a cross-sectional view illustrating an example of the cross-sectional structure of the memory device according to the embodiment during manufacturing.

FIG. 14 is a cross-sectional view illustrating an example of the cross-sectional structure of the memory device according to the embodiment during manufacturing.

FIG. 15 is a cross-sectional view illustrating an example of the cross-sectional structure of the memory device according to the embodiment during manufacturing.

FIG. 16 is a cross-sectional view illustrating an example of the cross-sectional structure of the memory device according to the embodiment during manufacturing.

FIG. 17 is a cross-sectional view illustrating an example of the cross-sectional structure of the memory device according to the embodiment during manufacturing.

FIG. 18 is a cross-sectional view illustrating an example of the cross-sectional structure of the memory device according to the embodiment during manufacturing.

FIG. 19 is a cross-sectional view illustrating an example of a cross-sectional structure in a memory area of a memory device according to a modification.

### DETAILED DESCRIPTION

Embodiments provide a memory device capable of improving reliability.

In general, according to one embodiment, a memory device includes: a plurality of insulator layers spaced apart from one another in a first direction; a plurality of conductor layers spaced apart from one another in the first direction, the plurality of insulator layers and the plurality of insulator layers alternately arranged along the first direction; and a memory pillar extending in the first direction to intersect the plurality of conductor layers. The plurality of conductor layers include a first conductor layer having a first portion and a second portion in contact with the memory pillar. The first portion is recessed relative to the second portion in a second direction intersecting the first direction. The plurality of insulator layers include a first insulator layer provided on a first surface of the first conductor layer closer to the first portion than the second portion, and a second insulator layer provided on a second surface of the first conductor layer closer to the second portion than the first portion, the second insulator layer being thinner than the first insulator layer in the first direction.

Hereinafter, embodiments will be described with reference to the drawings. Dimensions and ratios in the drawings are not necessarily the same as actual ones.

It is noted that, in the following description, elements having substantially the same functions and configurations are denoted by the same reference numerals. Different letters or numerals may be added to ends of the same reference numerals when specifically distinguishing between elements having similar configurations.

### 1. Configuration

### 1.1 Memory System

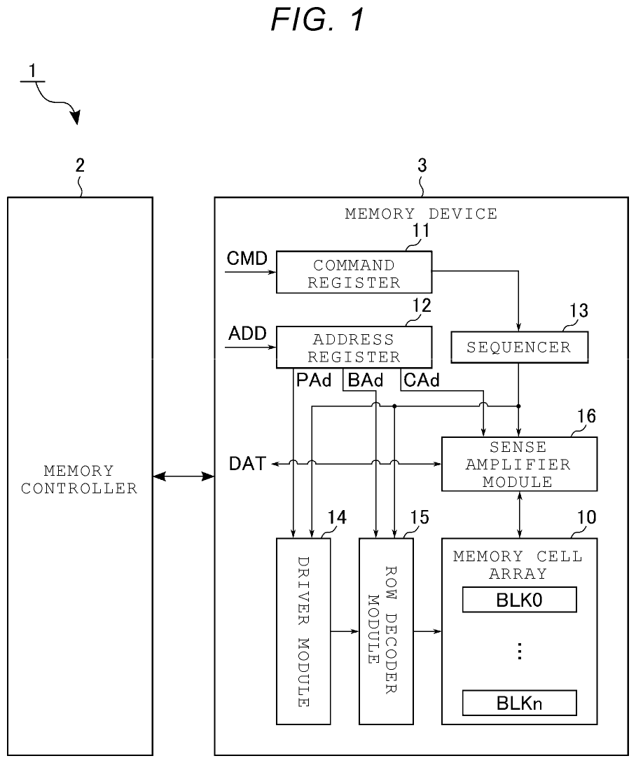

FIG. 1 is a block diagram illustrating a configuration of a memory system according to an embodiment. The memory system is a storage device configured to be connected to an external host (not illustrated). The memory system is, for example, a memory card such as an SD™ card, a universal flash storage (UFS), or a solid state drive (SSD). A memory system 1 includes a memory controller 2 and a memory device 3.

The memory controller 2 is configured with, for example, an integrated circuit such as a system-on-a-chip (SoC). The memory controller 2 controls the memory device 3 based on requests from the host. Specifically, for example, the memory controller 2 writes data write-requested from the host to the memory device 3. In addition, the memory controller 2 reads data read-requested from the host from the memory device 3 and transmits the data to the host.

The memory device 3 is a memory storing data in a non-volatile manner. The memory device 3 is, for example, a NAND flash memory.

Communication between the memory controller 2 and the memory device 3 conforms to, for example, a single data rate (SDR) interface, a toggle DDR (double data rate) interface, or an open NAND flash interface (ONFI).

### 1.2 Memory Device

Next, an internal configuration of the memory device according to the embodiment will be described with reference to the block diagram illustrated in FIG. 1. The memory device 3 includes, for example, a memory cell array 10, a command register 11, an address register 12, a sequencer 13, a driver module 14, a row decoder module 15, and a sense amplifier module 16.

The memory cell array 10 includes a plurality of blocks BLK0 to BLKn (n is an integer of 1 or more). The block BLK is a set of a plurality of memory cells capable of storing data in a non-volatile manner, and is used as, for example, a unit of data erasing. In addition, the memory cell array 10 is provided with a plurality of bit lines and a plurality of word lines. Each memory cell is associated with, for example, one bit line and one word line. A detailed configuration of the memory cell array 10 will be described later.

The command register 11 stores a command CMD received by the memory device 3 from the memory controller 2. The command CMD includes, for example, instructions for allowing the sequencer 13 to perform a read operation, a write operation, an erasing operation, and the like.

The address register 12 stores address information ADD received by the memory device 3 from the memory controller 2. The address information ADD includes, for example, a block address BAd, a page address PAd, and a column address CAd. For example, the block address BAd, the page address PAd, and the column address CAd are used to select the block BLK, the word lines, and the bit lines, respectively.

The sequencer 13 controls the entire operations of the memory device 3. For example, the sequencer 13 controls the driver module 14, the row decoder module 15, the sense amplifier module 16, and the like based on the command CMD stored in the command register 11 and executes the read operation, the write operation, the erasing operation, and the like.

The driver module 14 generates voltages used in the read operation, the write operation, the erasing operation, and the like. Then, the driver module 14 applies the generated voltage to a signal line corresponding to the selected word line based on, for example, the page address PAd stored in the address register 12.

The row decoder module 15 selects one block BLK in the corresponding memory cell array 10 based on the block address BAd stored in the address register 12. Then, the row decoder module 15 transfers, for example, a voltage applied to the signal line corresponding to the selected word line to the selected word line in the selected block BLK.

The sense amplifier module 16 applies a desired voltage to each bit line according to write data DAT received from the memory controller 2 in the write operation. In addition, in the read operation, the sense amplifier module 16 determines the data stored in the memory cell based on the voltage of the bit line and transfers a determination result to the memory controller 2 as read data DAT.

### 1.3 Circuit Configuration of Memory Cell Array

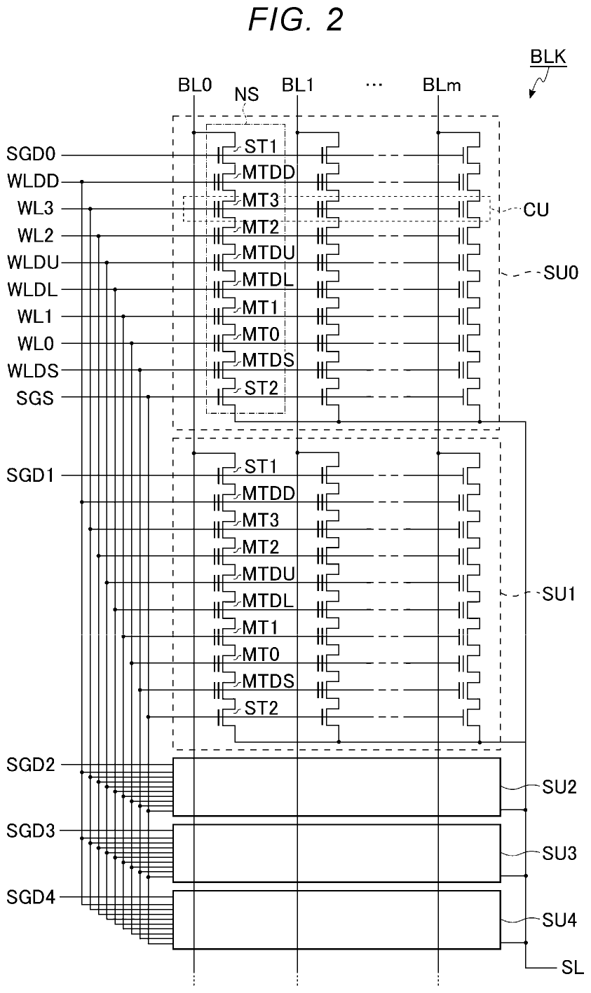

FIG. 2 is a circuit diagram illustrating an example of a circuit configuration of a memory cell array in the memory device according to the embodiment. FIG. 2 illustrates one block BLK among the plurality of blocks BLK in the memory cell array 10. As illustrated in FIG. 2, the block BLK includes, for example, five string units SU0 to SU4.

Each string unit SU includes a plurality of NAND strings NS respectively associated with bit lines BL0 to BLm (m is an integer of 1 or more). Each NAND string NS includes a plurality of memory cell transistors MT and select transistors ST1 and ST2. Each memory cell transistor MT can function as a storage capacity storing data in a non-volatile manner. The plurality of memory cell transistors MT connected in series are hereinafter also referred to as a “cell string”. Each of the select transistors ST1 and ST2 is used for selecting the string unit SU during various operations.

The cell string includes memory cell transistors MT0 to MT3, MTDS, MTDL, MTDU, and MTDD. The memory cell transistors MT0 to MT3 in the cell string are portions in which data from the host is stored in an area that can function as a memory capacity. The memory cell transistors MTDS, MTDL, MTDU, and MTDD in the cell string are portions in which the data from the host is not stored in the area that can function as a storage capacity. The memory cell transistors MT0 to MT3 are also referred to as “memory cells”, while the memory cell transistors MTDS, MTDL, MTDU, and MTDD are also referred to as “dummy cells”. In each NAND string NS, the memory cell transistors MTDS, MT0, MT1, MTDL, MTDU, MT2, MT3, and MTDD are connected in series, for example, in this order.

The drain of the select transistor ST1 is connected to an associated bit line BL, and the source of the select transistor ST1 is connected to an end portion of the cell string on a memory cell transistor MTDD side. The drain of the select transistor ST2 is connected to an end portion of the cell string on a memory cell transistor MTDS side. The source of the select transistor ST2 is connected to a source line SL. That is, the select transistors ST1 and ST2 are connected in series to the cell string so that the cell string is interposed therebetween.

In the same block BLK, control gates of the memory cell transistors MT0 to MT3, MTDS, MTDL, MTDU, and MTDD are connected to word lines WL0 to WL3, WLDS, WLDL, WLDU, and WLDD, respectively. Gates of the select transistors ST1 in the string units SU0 to SU4 are connected to select gate lines SGD0 to SGD4, respectively. Gates of the plurality of select transistors ST2 are connected to a select gate line SGS.

Different column addresses are assigned to the bit lines BL0 to BLm. Each bit line BL is shared by NAND strings NS to which the same column address is assigned among the plurality of blocks BLK. The word lines WL0 to WL3, WLDS, WLDL, WLDU, and WLDD are provided for each block BLK. The source line SL is shared, for example, among the plurality of blocks BLK.

The set of the plurality of memory cell transistors MT connected to the common word line WL in one string unit SU is referred to as, for example, a cell unit CU. For example, the storage capacity of the cell unit CU including the memory cell transistors MT each storing 1-bit data is defined as “1 page data”. The cell unit CU can have the storage capacity of two or more page data according to the number of bits of the data stored in the memory cell transistor MT.

It is noted that a circuit configuration of the memory cell array 10 in the memory device 3 according to the embodiment is not limited to the configuration described above. For example, the number of string units SU in each block BLK can be designed to be any number. The number of memory cells, the number of dummy cells, and the number of select transistors ST1 and ST2 in each NAND string NS can be designed to be any numbers. Each NAND string NS may not include at least one of the memory cell transistors MTDS, MTDL, MTDU, and MTDD.

### 1.4 Structure of Memory Cell Array

In the following, an example of a structure of the memory cell array in the memory device according to the embodiment will be described. It is noted that, in the drawings referred to below, an X direction corresponds to an extending direction of the word lines WL. A Y direction corresponds to an extending direction of the bit lines BL. An XY plane corresponds to a front surface of a semiconductor substrate used to form the memory device 3. A Z direction corresponds to a vertical direction relative to the XY plane. In a plan view, hatching is appropriately added to make the drawing easier to view. The hatching added to the plan view does not necessarily relate to the material or properties of elements to which the hatching is added. In a cross-sectional view, illustration of the configuration is omitted as appropriate to make the drawing easier to view.

### 1.4.1 Outline of Planar Layout

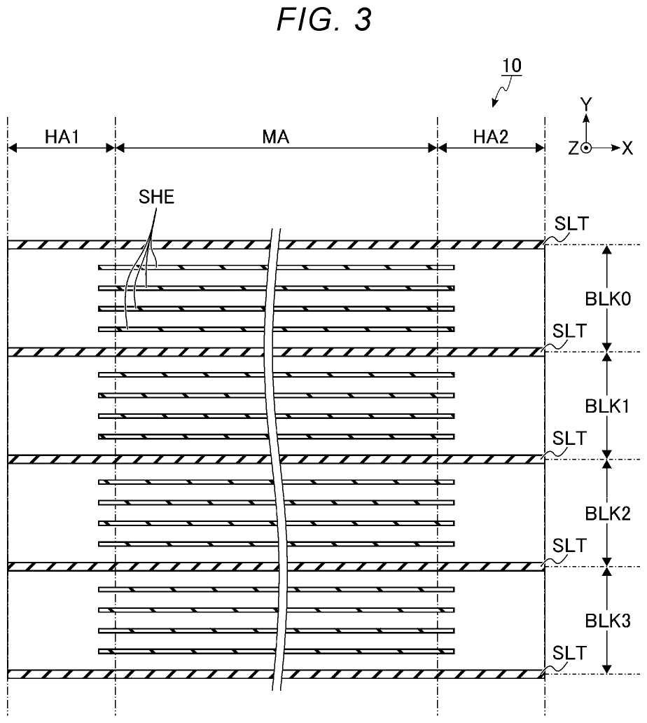

FIG. 3 is a plan view illustrating an example of a planar layout of the memory cell array in the memory device according to the embodiment. FIG. 3 illustrates areas corresponding to four blocks BLK0 to BLK3. As illustrated in FIG. 3, a planar layout of the memory cell array 10 is divided, for example, in the X direction into a memory area MA and lead areas HA1 and HA2. In addition, the memory cell array 10 includes a plurality of members SLT and SHE.

The memory area MA is disposed between the lead area HA1 and the lead area HA2. The memory area MA is an area including the plurality of NAND strings NS. Each of the lead areas HA1 and HA2 is an area used for connection between stacked wirings (for example, word lines WL0 to WL3, WLDS, WLDL, WLDU, and WLDD, and select gate lines SGD and SGS) and the row decoder module 15.

Each of the plurality of members SLT extends in the X direction and is lined up in the Y direction. Each member SLT crosses the memory area MA and the lead areas HA1 and HA2 in the X direction in a boundary area between the adjacent blocks BLK. In addition, each member SLT has a structure in which, for example, an insulator or a plate-shaped contact is buried. Each member SLT separates adjacent stacked wirings from each other through the member SLT.

Each of the plurality of members SHE extends in the X direction and is lined up in the Y direction. In the example of FIG. 3, four members SHE are located between adjacent members SLT, respectively. Each member SHE crosses the memory area MA in the X direction. Both ends of each member SHE are in the lead areas HA1 and HA2, respectively. In addition, each member SHE has a structure in which, for example, the insulator is buried. Each member SHE separates adjacent select gate lines SGD from each other through the member SHE.

In the planar layout of the memory cell array 10 described above, each area partitioned by the member SLT corresponds to one block BLK. In addition, each of the areas partitioned by the members SLT and SHE corresponds to one string unit SU. In the memory cell array 10, for example, the layout illustrated in FIG. 3 is repeatedly located in the Y direction.

It is noted that the planar layout of the memory cell array 10 in the memory device 3 according to the embodiment is not limited to the layout described above. For example, the number of members SHE located between the adjacent members SLT can be designed to be any number. The number of string units SU formed between the adjacent members SLT can be changed based on the number of members SHE located between the adjacent members SLT.

### 1.4.2 Memory Area (Planar Layout)

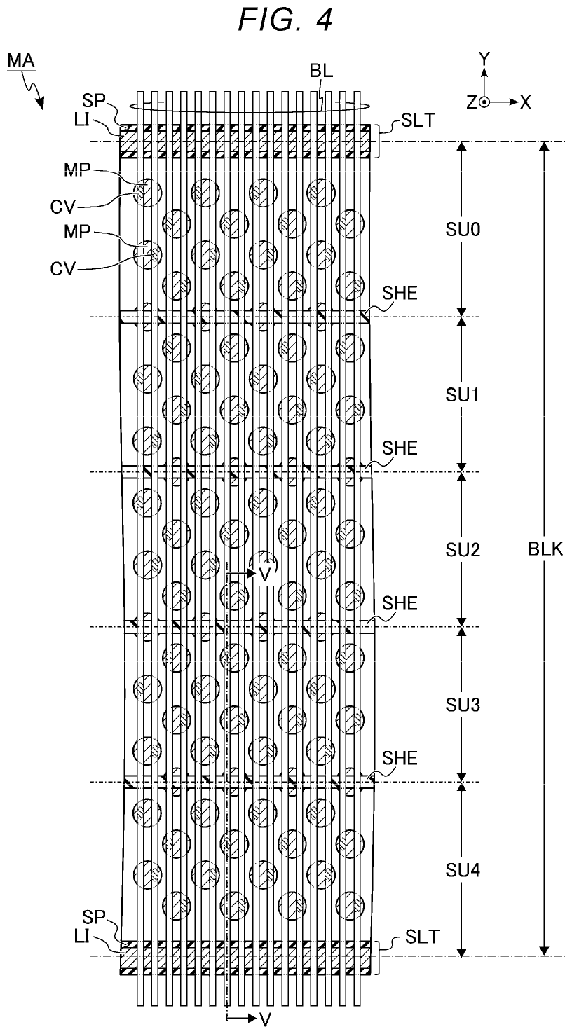

FIG. 4 is a plan view illustrating an example of the detailed planar layout in the memory area MA of the memory device according to the embodiment. FIG. 4 illustrates an area including one block BLK (that is, string units SU0 to SU4) and two members SLT interposing the block. As illustrated in FIG. 4, in the memory area MA, the memory cell array 10 includes a plurality of memory pillars MP, a plurality of contacts CV, and the plurality of bit lines BL. In addition, each member SLT also includes a contact LI and a spacer SP.

Each memory pillar MP functions, for example, as one NAND string NS. The plurality of memory pillars MP are located in, for example, 24 columns in a zigzag pattern in the area between the two adjacent members SLT. Then, for example, counting from the upper side of the paper, each of the 5th, 10th, 15th, and 20th memory pillars MP overlaps one member SHE.

Each of the plurality of bit lines BL extends in the Y direction and is lined up in the X direction. Each bit line BL overlaps at least one memory pillar MP for each string unit SU. The example of FIG. 4 illustrates the case where two bit lines BL overlap one memory pillar MP. One bit line BL among the plurality of bit lines BL overlapping the memory pillar MP and one corresponding memory pillar MP are electrically connected to each other via the contact CV.

For example, the contact CV between the memory pillar MP in contact with the member SHE and the bit line BL is omitted. In other words, the contact CV between the memory pillar MP and the bit line BL, which are in contact with two different select gate lines SGD, is omitted. The number and arrangement of memory pillars MP, members SHE, and the like between the adjacent members SLT are not limited to the configuration described with reference to FIG. 4 and may be changed as appropriate. The number of bit lines BL overlapping each memory pillar MP can be designed to be any number.

The contact LI is a conductor extending in an XZ plane. The spacer SP is an insulator provided on the side surfaces of the contact LI. In other words, the contact LI is surrounded by the spacer SP in plan view.

### Cross-Sectional Structure

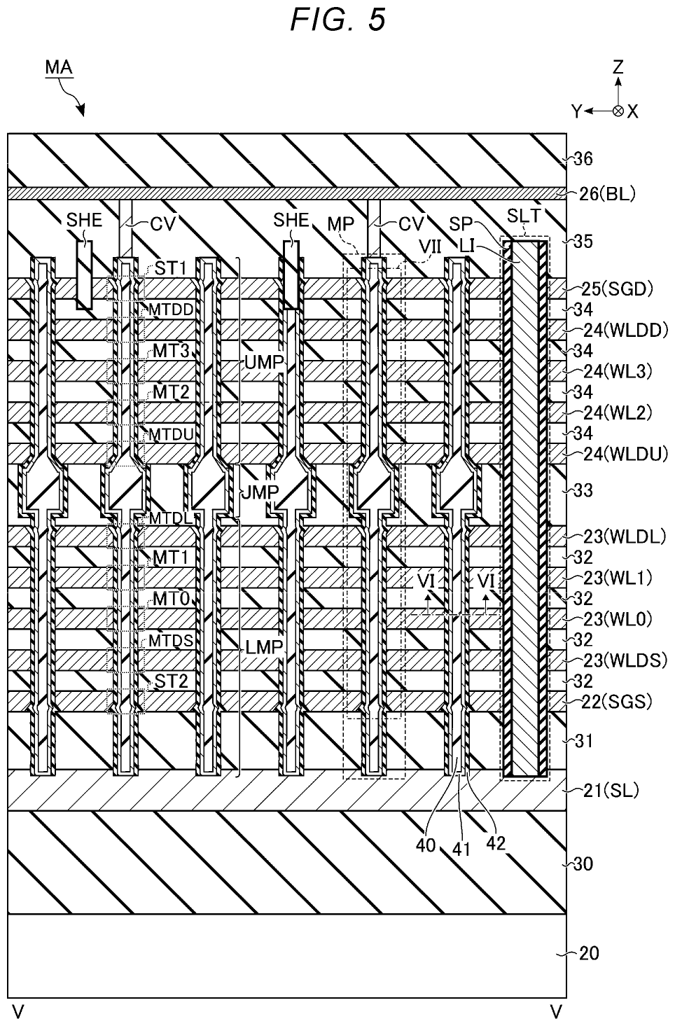

FIG. 5 is a cross-sectional view taken along line V-V in FIG. 4, illustrating an example of a cross-sectional structure in the memory area MA of the memory device according to the embodiment. As illustrated in FIG. 5, the memory cell array 10 further includes a semiconductor substrate 20, conductor layers 21 to 26, and insulator layers 30 to 36.

The semiconductor substrate 20 is, for example, a P-type semiconductor. The insulator layer 30 is provided on the upper surface of the semiconductor substrate 20. The semiconductor substrate 20 and the insulator layer 30 include circuits (not illustrated). The circuits in the semiconductor substrate 20 and the insulator layer 30 correspond to the row decoder module 15, the sense amplifier module 16, and the like. The conductor layer 21 is provided on the upper surface of the insulator layer 30.

The conductor layer 21 is, for example, a plate-shaped conductor extending along the XY plane. The conductor layer 21 is used as the source line SL. The conductor layer 21 contains, for example, silicon doped with phosphorus.

The insulator layer 31 and the conductor layer 22 are stacked in this order on the upper surface of the conductor layer 21. The conductor layer 22 is formed, for example, in a plate shape extending along the XY plane. The conductor layer 22 is used as the select gate line SGS. The conductor layer 22 contains, for example, tungsten. The insulator layer 31 contains, for example, silicon oxide.

The insulator layers 32 and the conductor layers 23 are alternately stacked in this order on the upper surface of the conductor layer 22. The conductor layer 23 is formed, for example, in a plate shape extending along the XY plane. A plurality of the stacked conductor layers 23 are used as word lines WLDS, WL0, WL1, and WLDL in order from a semiconductor substrate 20 side. The conductor layer 23 contains, for example, tungsten. The insulator layer 32 contains, for example, silicon oxide.

The insulator layer 33 is provided on the upper surface of the uppermost conductor layer 23. The insulator layer 33 contains, for example, silicon oxide.

The conductor layers 24 and the insulator layers 34 are alternately stacked in this order on the upper surface of the insulator layer 33. The conductor layer 24 is formed, for example, in a plate shape extending along the XY plane. A plurality of the stacked conductor layers 24 are used as word lines WLDU, WL2, WL3, and WLDD in order from the semiconductor substrate 20 side. The conductor layer 24 contains, for example, tungsten. The insulator layer 34 contains, for example, silicon oxide.

The conductor layer 25 and the insulator layer 35 are stacked in this order on the upper surface of the uppermost insulator layer 34. The conductor layer 25 is formed, for example, in a plate shape extending along the XY plane. The conductor layer 25 is used as the select gate line SGD. The conductor layer 25 contains, for example, tungsten. The insulator layer 35 contains, for example, silicon oxide.

The conductor layer 26 is provided on the upper surface of the insulator layer 35. The conductor layer 26 is formed, for example, in a line shape extending in the Y direction and used as the bit line BL. That is, in an area not illustrated, a plurality of the conductor layers 26 are lined up in the X direction. The conductor layer 26 contains, for example, copper. The insulator layer 36 is provided on the upper surface of the conductor layer 26. The insulator layer 36 contains, for example, silicon oxide.

The film thicknesses of the insulator layers 32 and 34 are substantially equal to each other. The film thickness of each of the insulator layers 31, 33, and 35 is larger than the film thickness of each of the insulator layers 32 and 34. That is, the insulator layer in contact with the lower surface of each of the conductor layer 22 and the lowermost conductor layer 24 is thicker than the insulator layer in contact with the upper surface of each of the conductor layer 22 and the lowermost conductor layer 24. The insulator layer in contact with the upper surface of each of the uppermost conductor layer 23 and the conductor layer 25 is thicker than the insulator layer in contact with the lower surface of each of the uppermost conductor layer 23 and the conductor layer 25.

Each memory pillar MP includes a lower portion LMP, a coupling portion JMP, and an upper portion UMP. A lower end of the lower portion LMP reaches the conductor layer 21. The lower portion LMP extends in the Z direction so as to intersect the conductor layers 22 and 23. The coupling portion JMP is connected to an upper end of the lower portion LMP and provided in the insulator layer 33. The upper portion UMP is connected to the upper end of the coupling portion JMP and extends in the Z direction so as to intersect the conductor layers 24 and 25. The upper end of the upper portion UMP reaches the insulator layer 35.

The cross-sectional area (XY cross-sectional area) of the coupling portion JMP cut by the XY plane is larger than the XY cross-sectional area of the upper end of the lower portion LMP and the XY cross-sectional area of a lower end of the upper portion UMP. The side surfaces of the coupling portion JMP are deviated from and do not coincide with the extension of the side surfaces of the lower portion LMP and the extension of the side surfaces of the upper portion UMP. Such deviation in the side surfaces occurs not only in a YZ cross section illustrated in FIG. 5 but also in any cross section including the Z direction.

In addition, each memory pillar MP includes, for example, a core film 40, a semiconductor film 41, and a stacked film 42. The core film 40 extends in the Z direction. For example, the upper end of the core film 40 is located above the conductor layer 25. The lower end of the core film 40 is located in the same layer as the conductor layer 21. The semiconductor film 41 covers the periphery of the core film 40. The semiconductor film 41 is in contact with the conductor layer 21 at the lower end of the lower portion LMP. The stacked film 42 covers side surfaces and a bottom surface of the semiconductor film 41 except for the portion where the semiconductor film 41 and the conductor layer 21 are in contact with each other. The core film 40 contains an insulator such as silicon oxide. The semiconductor film 41 contains, for example, silicon.

The portion where the memory pillar MP and the conductor layer 22 intersect functions as the select transistor ST2. The portion where the memory pillar MP and one conductor layer 23 or one conductor layer 24 intersect functions as one memory cell transistor MT. The portion where the memory pillar MP and the conductor layer 25 intersect functions as the select transistor ST1.

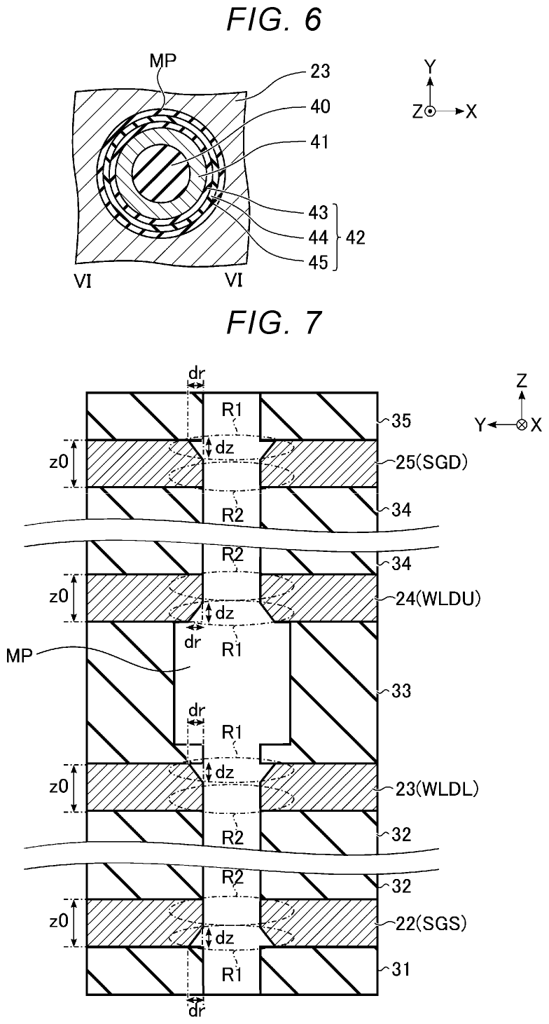

FIG. 6 is a cross-sectional view taken along line VI-VI in FIG. 5, illustrating an example of a cross-sectional structure of a memory pillar in the memory device according to the embodiment. FIG. 6 illustrates a cross-sectional structure of the memory pillar MP in a layer parallel to the XY plane and including the conductor layer 23. As illustrated in FIG. 6, the stacked film 42 includes, for example, a tunnel insulating film 43, a charge storage film 44, and a block insulating film 45.

In the cross section including the conductor layer 23, the core film 40 is provided, for example, in the central portion of the memory pillar MP. The semiconductor film 41 surrounds the side surfaces of the core film 40. The tunnel insulating film 43 surrounds the side surfaces of the semiconductor film 41. The charge storage film 44 surrounds the side surfaces of the tunnel insulating film 43. The block insulating film 45 surrounds the side surfaces of the charge storage film 44. The conductor layer 23 surrounds the side surfaces of the block insulating film 45.

The semiconductor film 41 is used as channels (current paths) of the memory cell transistors MT0 to MT3, MTDS, MTDL, MTDU, and MTDD and the select transistors ST1 and ST2. Each of the tunnel insulating film 43 and the block insulating film 45 contains, for example, silicon oxide. The charge storage film 44 has a function of storing charges and contains, for example, silicon nitride. Therefore, each memory pillar MP can function as one NAND string NS.

FIG. 7 is a cross-sectional view of an area VII in FIG. 5, illustrating an example of the cross-sectional structure in the memory area MA of the memory device according to the embodiment. FIG. 7 illustrates a detailed YZ cross-sectional structure of a portion of the memory cell array 10 where each of the conductor layer 22, the uppermost conductor layer 23, the lowermost conductor layer 24, and the conductor layer 25 intersects the memory pillar MP. It is noted that, in FIG. 7, illustration of the details of the cross-sectional structure of the memory pillar MP is omitted.

As illustrated in FIG. 7, the memory pillars MP has a portion with a locally larger diameter than the surrounding in the portion intersecting each of the conductor layer 22, the uppermost conductor layer 23, the lowermost conductor layer 24, and the conductor layer 25. In other words, each of the conductor layer 22, the uppermost conductor layer 23, the lowermost conductor layer 24, and the conductor layer 25 has a recessed portion R1 which is recessed in a direction (radial direction) where a diameter of the memory pillar MP increases in a boundary area in contact with the memory pillar MP. The recessed portion R1 is lined up in the Z direction with a non-recessed portion R2, which is not recessed in the radial direction, in the boundary area in contact with the memory pillar MP.

More specifically, the conductor layer 22 and the lowermost conductor layer 24 are recessed toward the lower surface from between the lower surface and the upper surface, and an amount of recession is greatest at the lower surface. The uppermost conductor layer 23 and the conductor layer 25 are recessed toward the upper surface from between the lower surface and the upper surface, and the amount of recession is greatest at the upper surface. A maximum value dr of the amount of recession of each of the conductor layer 22, the uppermost conductor layer 23, the lowermost conductor layer 24, and the conductor layer 25 is, for example, 3 nanometers (nm) or more. A thickness dz of the recessed portion R1 of each of the conductor layer 22, the uppermost conductor layer 23, the lowermost conductor layer 24, and the conductor layer 25 is, for example, 7 nm or more and 13 nm or less. The thickness dz of the recessed portion R1 of each of the conductor layer 22, the uppermost conductor layer 23, the lowermost conductor layer 24, and the conductor layer 25 relative to a film thickness z0 (that is, a gate length of the memory cell transistor MT) of each of the uppermost conductor layer 23, the lowermost conductor layer 24, and the conductor layer 25 is, for example, 35% or more and 50% or less.

A diameter of a portion of the memory pillar MP intersecting the recessed portion R1 is larger than a diameter of a portion of the memory pillar MP intersecting the non-recessed portion R2. It is noted that, although omitted in FIG. 7, a thickness of the block insulating film 45 in the portion of the memory pillar MP intersecting the recessed portion R1 may be larger than a thickness in the portion of the memory pillar MP intersecting the non-recessed portion R2 or may be substantially equal to the thickness in the portion of the memory pillar MP intersecting the non-recessed portion R2.

Referring back to FIG. 5, the cross-sectional structure of the memory cell array 10 will be described.

The columnar contact CV is provided on the upper surface of the semiconductor film 41 in the memory pillar MP. In the illustrated area, one contact CV corresponding to one memory pillar MP out of the two memory pillars MP in each of the cross-sectional regions partitioned by the members SLT and SHE is displayed. In the memory area MA, the memory pillars MP which do not overlap the member SHE and are not connected to the contacts CV are connected to the corresponding contacts CV in the area not illustrated.

One conductor layer 26, that is, one bit line BL is in contact with the upper surface of the contact CV. One conductor layer 26 is in contact with one contact CV in each of the spaces partitioned by the members SLT and SHE. That is, in each of the conductor layers 26, the memory pillar MP provided between the adjacent members SLT and SHE and the memory pillar MP provided between the two adjacent members SHE are electrically connected to each other.

The member SLT separates the conductor layers 22 to 25. The contact LI in the member SLT is provided along the spacer SP. The upper end of the contact LI is located in a layer between the conductor layer 25 and the conductor layer 26. The lower end of the contact LI is in contact with the conductor layer 21. The spacer SP is provided between the contact LI and the conductor layers 22 to 25. The spacer SP separates and insulates the contacts LI from the conductor layers 22 to 25.

The member SHE separates the conductor layer 25. An upper end of the member SHE is located in the layer between the conductor layer 25 and the conductor layer 26. A lower end of the member SHE is located in the layer between the uppermost conductor layer 24 and the conductor layer 25. The member SHE contains an insulator such as silicon oxide. The upper end of the member SHE and the upper end of the member SLT may be aligned or may not be aligned. In addition, the upper end of the member SHE and the upper end of the memory pillar MP may be aligned or may not be aligned. In addition, each of the conductor layers 22 to 25 can take any number. For example, in a case where the plurality of conductor layers 25 are provided, the lower end of the member SHE is located between the uppermost conductor layer 24 and the lowermost conductor layer 25. That is, the lower end of the member SHE becomes deeper according to the number of conductor layers 25.

### 2. Method for Manufacturing Memory Device

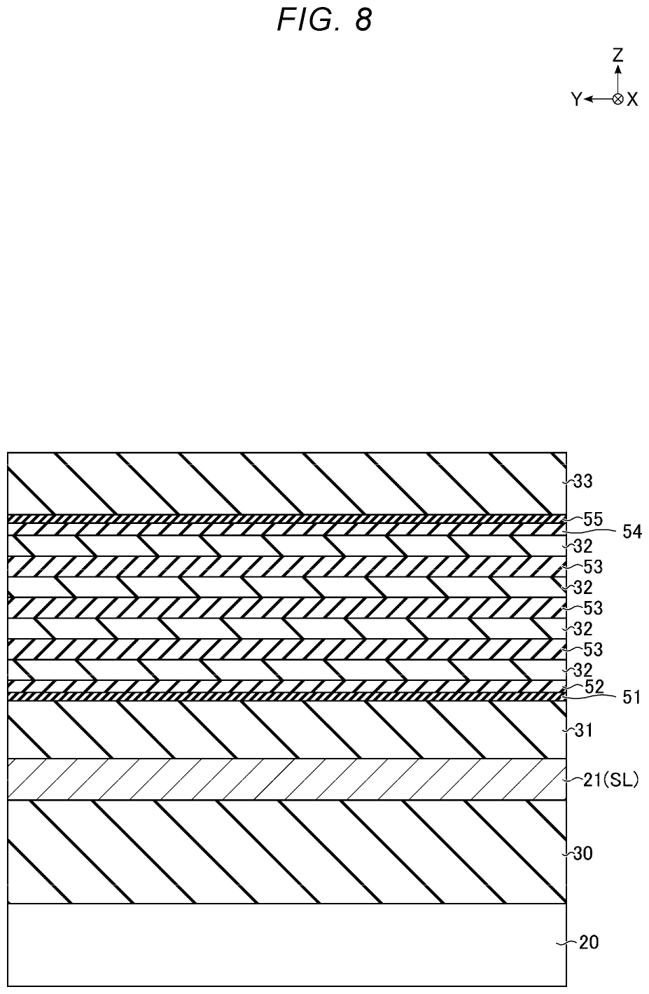

Each of FIGS. 8 to 18 illustrates an example of a planar layout or a cross-sectional structure of the memory device according to the embodiment during manufacturing. The illustrated cross-sectional structure corresponds to FIG. 5. In the following, an example of a manufacturing process of the memory cell array 10 in the memory device 3 will be described.

First, as illustrated in FIG. 8, the insulator layer 30 is formed on the upper surface of the semiconductor substrate 20. The conductor layer 21 and the insulator layer 31 are stacked in this order on the upper surface of the insulator layer 30. A sacrifice layer 51, a sacrifice layer 52, and the insulator layer 32 are stacked in this order on the upper surface of the insulator layer 31. A sacrifice layer 53 and the insulator layer 32 are repeatedly stacked in this order on the upper surface of the insulator layer 32. A sacrifice layer 54, a sacrifice layer 55, and the insulator layer 33 are stacked in this order on the upper surface of the uppermost insulator layer 32.

The film thickness of each of the insulator layers 31 and 33 is larger than the film thickness of the insulator layer 32. The film thickness of each of the sacrifice layers 51 and 55 is, for example, 7 nm or more and 13 nm or less. The ratio of the film thickness of the sacrifice layer 51 to a sum of the film thicknesses of the sacrifice layers 51 and 52 is, for example, 35% or more and 50% or less. The ratio of the film thickness of the sacrifice layer 55 to a sum of the film thicknesses of the sacrifice layers 54 and 55 is, for example, 35% or more and 50% or less. The sum of the film thicknesses of the sacrifice layers 51 and 52, the film thickness of the sacrifice layer 53, and the sum of the film thicknesses of the sacrifice layers 54 and 55 are substantially equal to each other. The sacrifice layers 52, 53, and 54 contain, for example, silicon nitride (SiN). The sacrifice layers 51 and 55 contain, for example, oxygen-doped SiN.

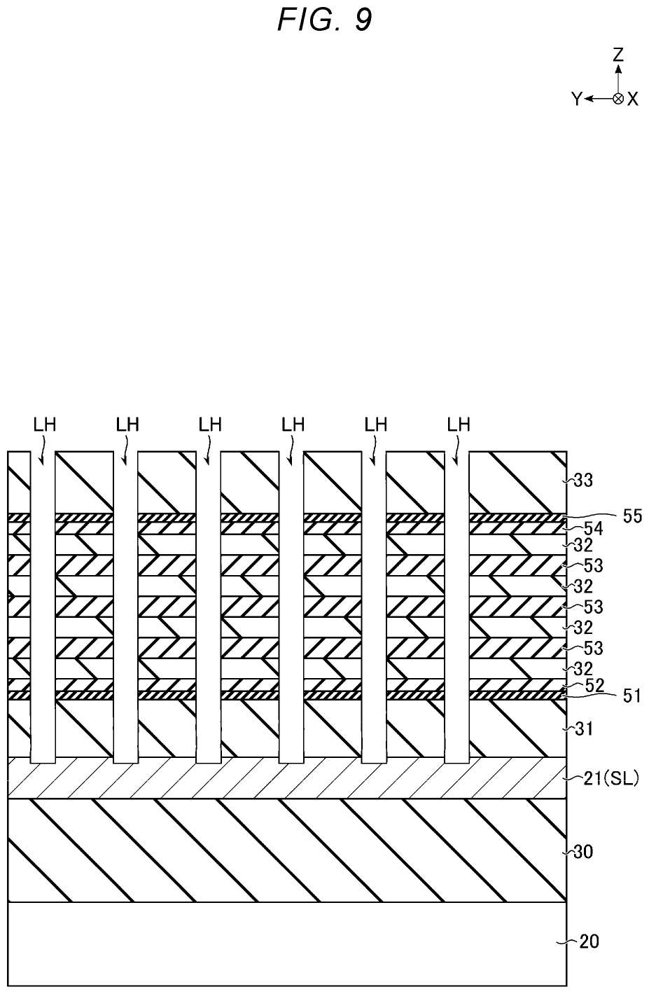

Next, as illustrated in FIG. 9, a mask having an opened area corresponding to the lower portion LMP of the memory pillar MP is formed by photolithography or the like. Then, by anisotropic etching using the mask, for example, a plurality of holes LH penetrating through each of the insulator layers 31, 32 and 33 and the sacrifice layers 51, 52, 53, 54, and 55 are formed. The hole LH corresponds to the lower portion LMP of the memory pillar MP. A portion of the conductor layer 21 is exposed to a bottom portion of each of the plurality of holes LH. For example, reactive ion etching (RIE) is used for a process of the anisotropic etching.

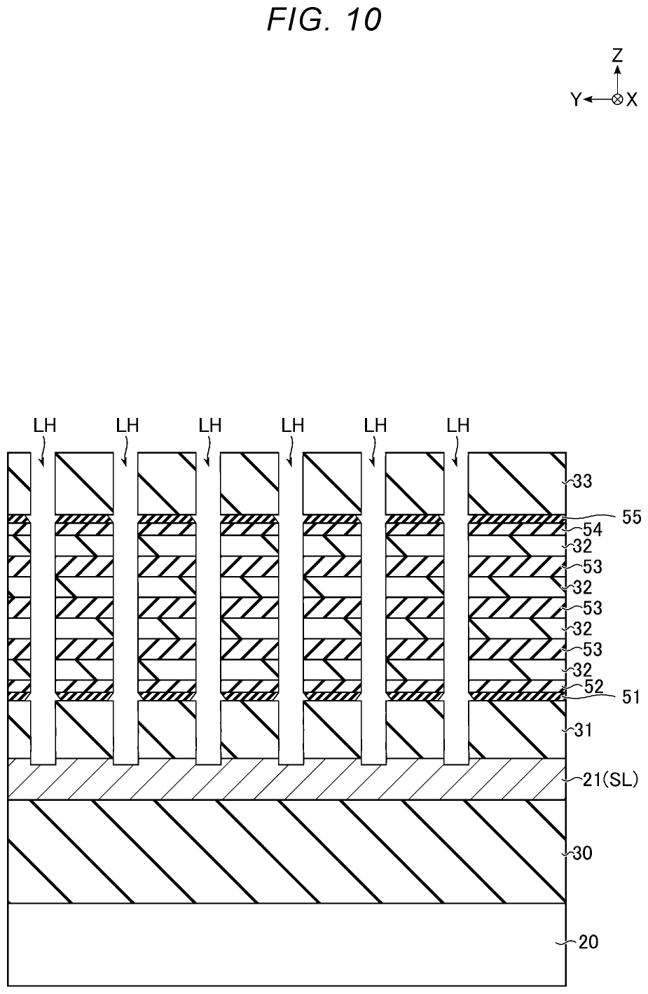

Next, as illustrated in FIG. 10, portions of the sacrifice layers 51, 52, 53, 54, and 55 are removed through the plurality of holes LH, for example, by wet etching. Accordingly, the sacrifice layers 51, 52, 53, 54, and 55 are recessed relative to the insulator layers 31, 32, and 33 at the boundaries with the plurality of holes LH. It is noted that, in the corresponding drawings, amounts of recession of the sacrifice layers 51, 52, 53, 54, and 55 relative to the insulator layers 31, 32, and 33 are omitted.

Herein, an etching rate of the sacrifice layers 51 and 55 in a wet etching process is higher than an etching rate of the sacrifice layers 52, 53, and 54. For this reason, the amounts of recession of the sacrifice layers 51 and 55 are significantly larger than the amounts of recession of the sacrifice layers 52, 53, and 54. More specifically, the amount of recession of the sacrifice layer 51 increases from the surface in contact with the sacrifice layer 52 toward the surface in contact with the insulator layer 31. The amount of recession of the sacrifice layer 55 increases from the surface in contact with the sacrifice layer 54 toward the surface in contact with the insulator layer 33. The maximum value of the amount of recession of each of the sacrifice layers 51 and 55 is, for example, 3 nm or more.

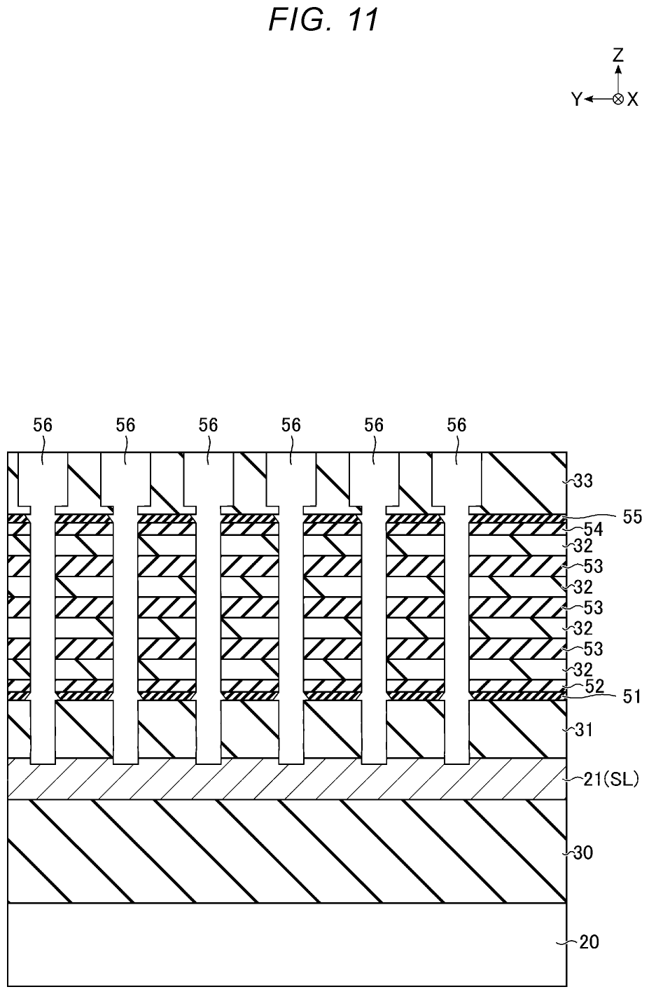

Next, as illustrated in FIG. 11, the plurality of holes LH are filled with a sacrifice film 56. The sacrifice film 56 contains, for example, amorphous silicon. Subsequently, some of the portion of the sacrifice film 56 intersecting the insulator layer 33 is etched back. The space formed by etchback is radially expanded by, for example, wet etching. The space expanded by the wet etching corresponds to the coupling portion JMP of the memory pillar MP. The space corresponding to the coupling portion JMP of the memory pillar MP is filled with the sacrifice film 56. After that, an upper surface of a stacked structure is planarized by, for example, chemical mechanical polishing (CMP).

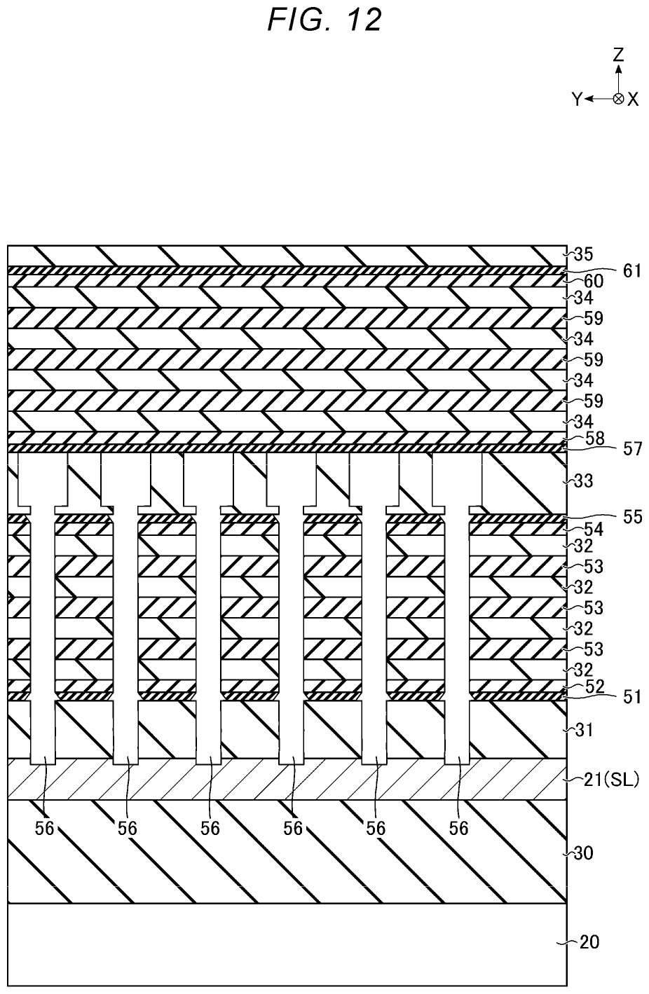

Next, as illustrated in FIG. 12, a sacrifice layer 57, a sacrifice layer 58, and the insulator layer 34 are stacked in this order on the upper surfaces of the insulator layer 33 and the sacrifice film 56. A sacrifice layer 59 and the insulator layer 34 are repeatedly stacked in this order on the upper surface of the insulator layer 34. A sacrifice layer 60, a sacrifice layer 61, and the insulator layer 35 are stacked in this order on the upper surface of the uppermost insulator layer 34.

The film thickness of the insulator layer 35 is larger than the film thickness of the insulator layer 34. The film thickness of each of the sacrifice layers 57 and 61 is, for example, 7 nm or more and 13 nm or less. The ratio of the film thickness of the sacrifice layer 57 to a sum of the film thicknesses of the sacrifice layers 57 and 58 is, for example, 35% or more and 50% or less. The ratio of the film thickness of the sacrifice layer 61 to a sum of the film thicknesses of the sacrifice layers 60 and 61 is, for example, 35% or more and 50% or less. The sum of the film thicknesses of the sacrifice layers 57 and 58, the film thickness of the sacrifice layer 59, and the sum of the film thicknesses of the sacrifice layers 60 and 61 are substantially equal to each other. The sacrifice layers 58, 59, and 60 contain, for example, SiN. The sacrifice layers 57 and 61 contain, for example, oxygen-doped SiN.

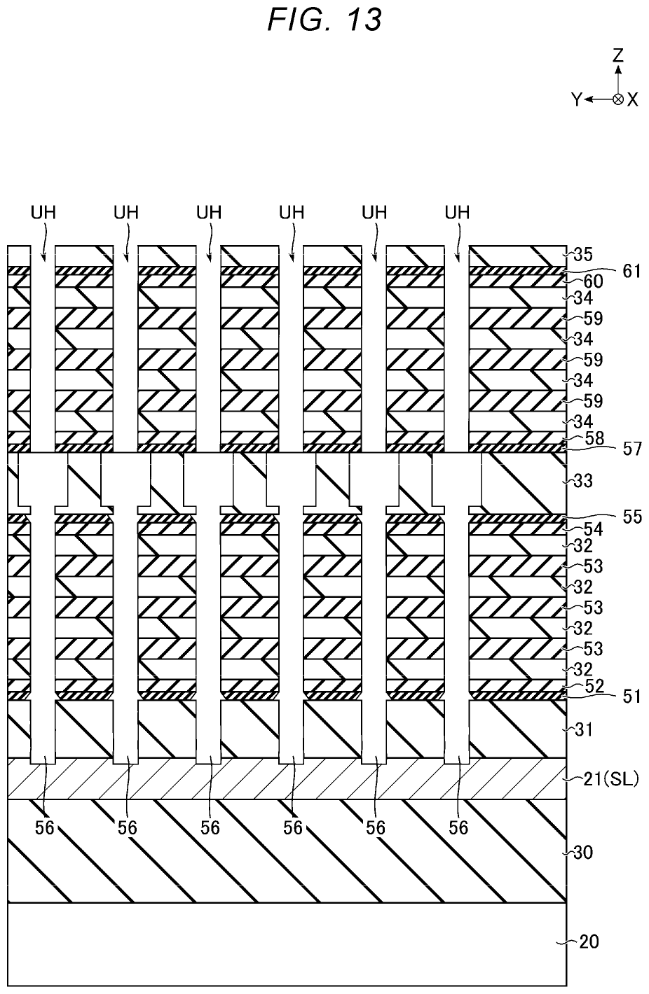

Next, as illustrated in FIG. 13, a mask having an opened portion corresponding to the upper portion UMP of the memory pillar MP is formed by photolithography or the like. Then, by anisotropic etching using the mask, for example, a plurality of holes UH penetrating through each of the insulator layers 34 and 35 and the sacrifice layers 57, 58, 59, 60, and 61 are formed. The hole UH corresponds to the upper portion UMP of the memory pillar MP. A portion of the sacrifice film 56 is exposed to a bottom portion of each of the plurality of holes UH. For example, RIE is used for a process of the anisotropic etching.

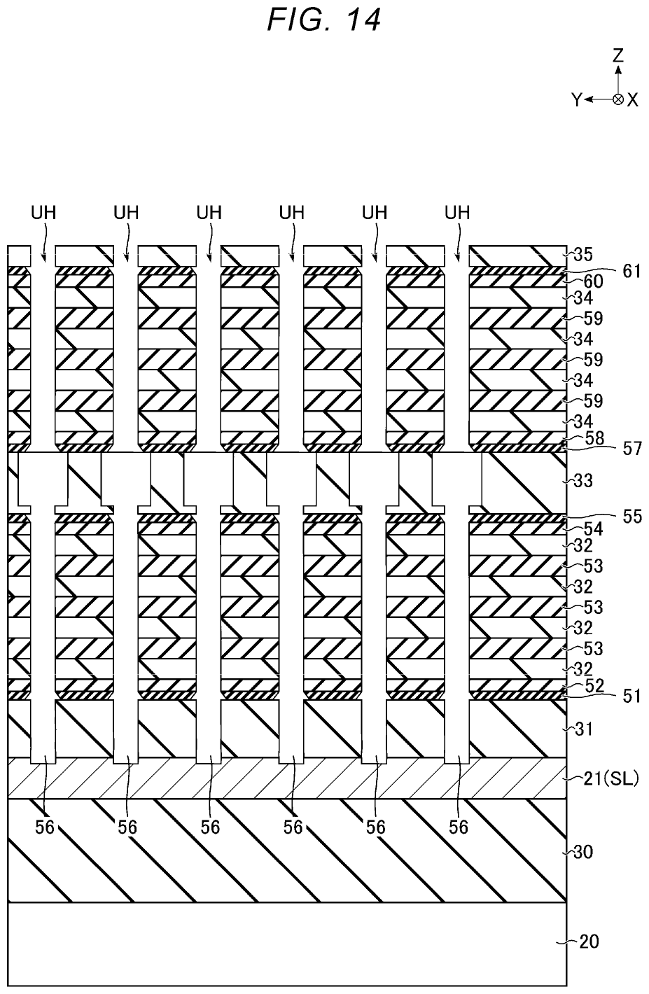

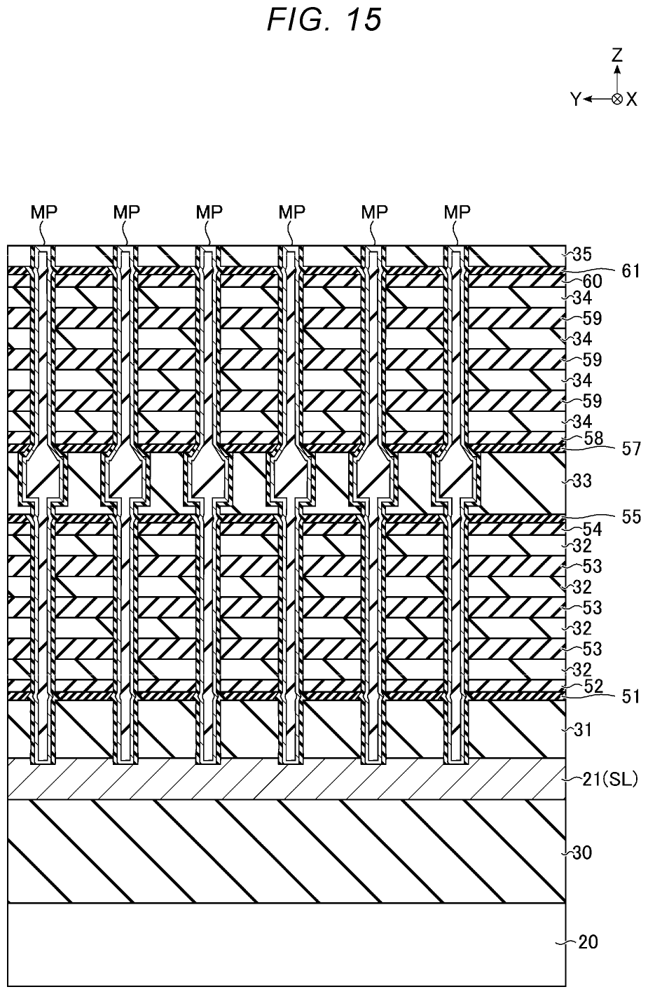

Next, as illustrated in FIG. 14, portions of the sacrifice layers 57, 58, 59, 60, and 61 are removed through the plurality of holes UH, for example, by wet etching. Accordingly, the sacrifice layers 57, 58, 59, 60, and 61 are recessed relative to the insulator layers 34 and 35 at the boundaries with the plurality of holes UH. It is noted that, in the corresponding drawings, amounts of recession of the sacrifice layers 57, 58, 59, 60, and 61 relative to the insulator layers 34 and 35 are omitted.

Herein, an etching rate of the sacrifice layers 57 and 61 in a wet etching process is higher than an etching rate of the sacrifice layers 58, 59, and 60. For this reason, the amounts of recession of the sacrifice layers 57 and 61 are significantly larger than the amounts of recession of the sacrifice layers 58, 59, and 60. More specifically, the amount of recession of the sacrifice layer 57 increases from the surface in contact with the sacrifice layer 58 toward the surface in contact with the sacrifice film 56. The amount of recession of the sacrifice layer 61 increases from the surface in contact with the sacrifice layer 60 toward the surface in contact with the insulator layer 35. The maximum value of the amount of recession of each of the sacrifice layers 57 and 61 is, for example, 3 nm or more.

Next, as illustrated in FIG. 15, the sacrifice film 56 is removed through each hole UH. Subsequently, the memory pillar MP is formed in each hole UH. Specifically, the block insulating film 45, the charge storage film 44, and the tunnel insulating film 43 are formed in this order in the plurality of holes UH. Then, the block insulating film 45, the charge storage film 44, and the tunnel insulating film 43 formed at the bottom portion of each hole UH are removed. Accordingly, the conductor layer 21 is exposed to the bottom portion of each hole UH. Then, the semiconductor film 41 and the core film 40 are formed in this order in the plurality of holes UH. Accordingly, the conductor layer 21 and the semiconductor film 41 are in contact with each other in each hole UH. After that, the plurality of holes UH are filled with the core film 40. Then, a portion of the core film 40 provided in the upper portion of each hole UH is removed, and the semiconductor film 41 is formed in the removed portion. The upper surface of the stacked structure is planarized by, for example, CMP.

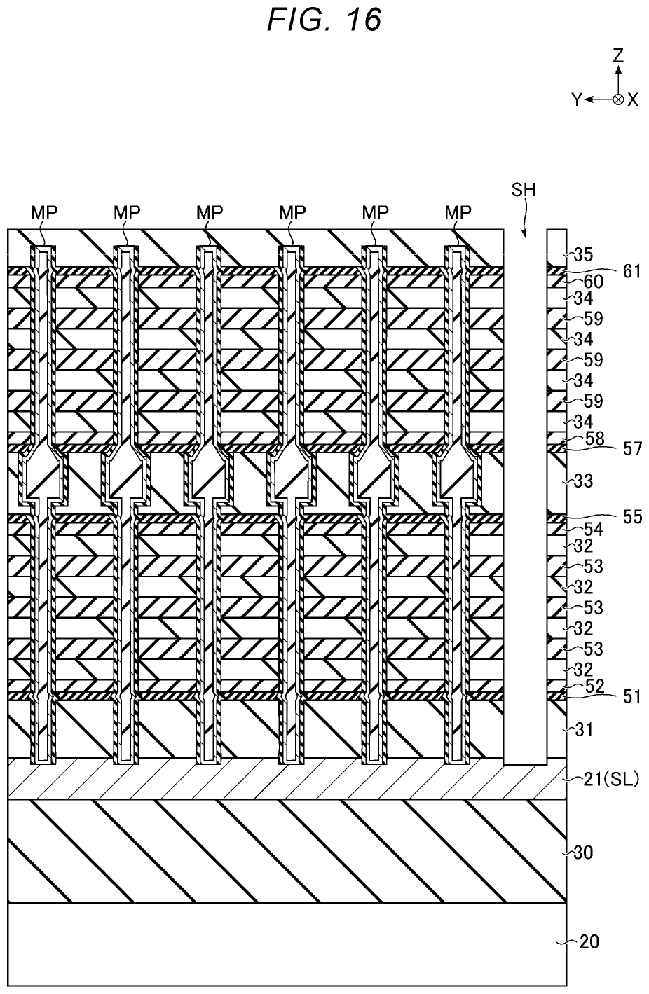

Next, as illustrated in FIG. 16, a mask having an opened area corresponding to the member SLT is formed by photolithography or the like. Then, by anisotropic etching using the mask, for example, a plurality of slits SH penetrating through each of the insulator layers 31, 32, 33, 34, and 35 and the sacrifice layers 51, 52, 53, 54, 55, 57, 58, 59, 60, and 61 are formed. Accordingly, the conductor layer 21 is exposed to the inside of each slit SH.

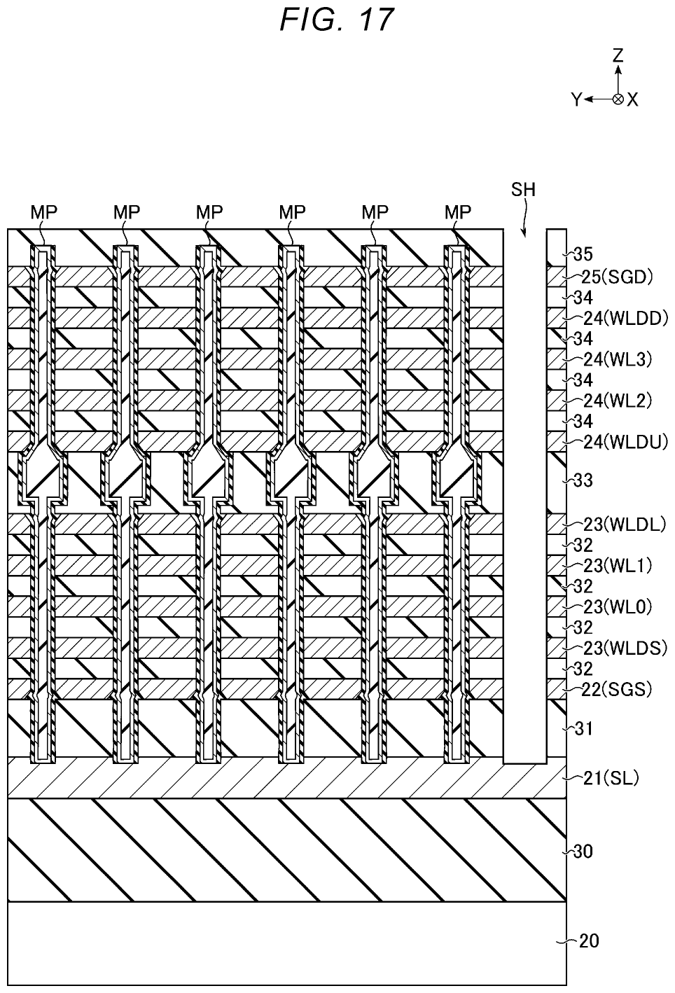

Next, as illustrated in FIG. 17, the sacrifice layers 51, 52, 53, 54, 55, 57, 58, 59, 60, and 61 are selectively removed through the slit SH by, for example, wet etching using hot phosphoric acid or the like. Then, the conductor is buried through the slit SH in the space from which the sacrifice layers 51, 52, 53, 54, 55, 57, 58, 59, 60, and 61 are removed. For example, chemical vapor deposition (CVD) is used to form the conductor in this process. After that, the conductor formed in the slit SH is removed by an etchback process. Accordingly, the conductor formed in the slit SH is separated into the plurality of conductor layers. Accordingly, the conductor layer 22 functioning as the select gate line SGS, the plurality of conductor layers 23 functioning as the word lines WLDS, WL0, WL1, and WLDL, respectively, the plurality of conductor layers 24 functioning as the word lines WLDU, WL2, WL3, and WLDD, and the conductor layer 25 functioning as the select gate line SGD are formed. The conductor layers 22, 23, 24, and 25 formed in this process may contain a barrier metal. In this case, in forming the conductor after removing the sacrifice layers 51, 52, 53, 54, 55, 57, 58, 59, 60, and 61, for example, titanium nitride is deposited as the barrier metal, and then, tungsten is formed.

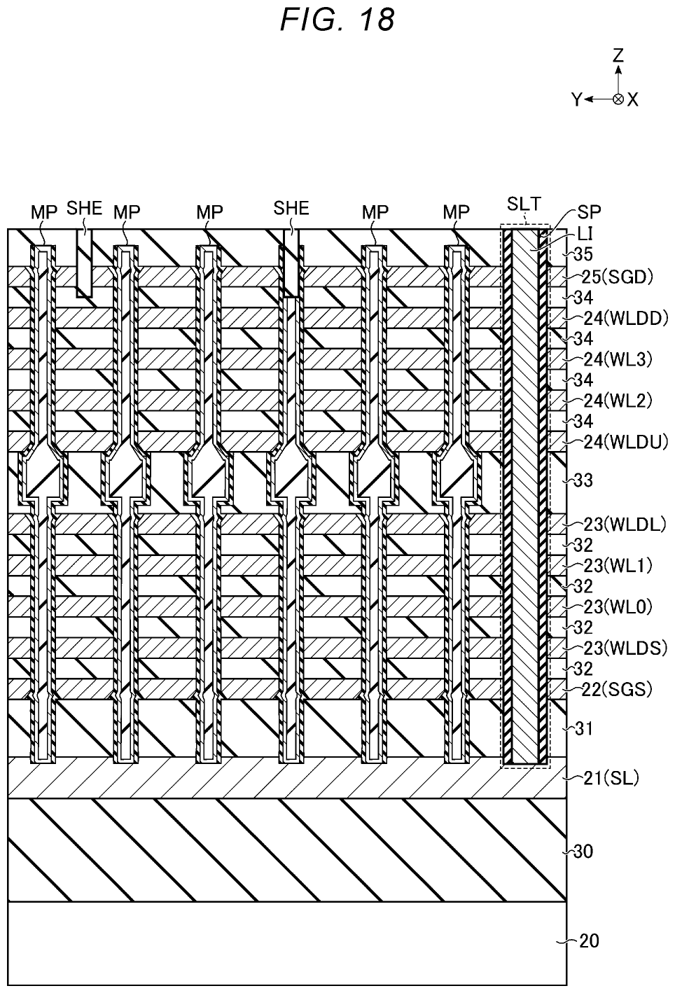

Next, as illustrated in FIG. 18, the insulator and the conductor are formed in this order in the plurality of slits SH. Each slit SH is filled with the conductor. The upper surface of the stacked structure is planarized by, for example, CMP. Accordingly, the member SLT is formed. After that, the member SHE is formed.

The memory cell array 10 is formed by the manufacturing process described above. It is noted that the manufacturing process described above is merely an example, and is not limited thereto. For example, other processes may be inserted between the manufacturing processes, or some processes may be omitted or integrated. Moreover, each manufacturing process may be replaced in a possible range.

### 3. Effects Related to Embodiment

According to the embodiment, each of the conductor layer 22, the uppermost conductor layer 23, the lowermost conductor layer 24, and the conductor layer 25 has the recessed portion R1 and the non-recessed portion R2 lined up in the Z direction in the boundary with the memory pillar MP. Accordingly, the distance between the conductor layer in the recessed portion R1 and the memory pillar MP can be increased, and the curvature of the conductor layer in the recessed portion R1 can be alleviated. For this reason, during the write operation and the erasing operation, a strong electric field (electric field concentration) formed between an end portion of each of the conductor layer 22, the uppermost conductor layer 23, the lowermost conductor layer 24, and the conductor layer 25 and the memory pillar MP can be alleviated. Then, during the write operation and the erasing operation, a back tunneling phenomenon where charges are accumulated in the charge storage film 44 at the recessed portion R1 of each of the conductor layer 22, the uppermost conductor layer 23, the lowermost conductor layer 24, and the conductor layer 25 can be prevented. Therefore, an unintended increase in the threshold voltages of the memory cell transistors MTDU and MTDL and the select transistors ST1 and ST2 due to the write operation and the erasing operation can be reduced, and furthermore, the reliability of the memory device 3 can be improved.

In addition, when the film thickness of one of two insulator layers adjacent to the conductor layer is larger than the film thickness of the other, the electric field concentration can occur at the end portion of the conductor layer on the side of the insulator layer with a large film thickness. According to the embodiment, the recessed portion R1 of the conductor layer 22 is provided on the insulator layer 31 side. The recessed portion R1 of the uppermost conductor layer 23 and the recessed portion R1 of the lowermost conductor layer 24 are provided on the insulator layer 33 side. The recessed portion R1 of the conductor layer 25 is provided on the insulator layer 35 side. Accordingly, the recessed portion R1 can be provided in the portion of the boundary between the conductor layer and the memory pillar MP, where the electric field concentration is likely to occur. For this reason, the reliability of the memory device 3 can be improved.

Further, the maximum value dr of the amount of recession of the recessed portion R1 is 3 nm or more. The film thickness dz of the recessed portion R1 is 7 nm or more and 13 nm or less. The ratio of the film thickness dz of the recessed portion R1 to the sum z0 of the film thicknesses of the recessed portion R1 and the non-recessed portion R2 is 35% or more and 50% or less. Accordingly, it is possible to obtain an optimum shape capable of alleviating the electric field concentration that occurs during the write operation and the erasing operation.

### 4. Modification and the Like

Various modifications may be applied to the above-described embodiments.

In the above-described embodiments, the case where a portion of one conductor layer corresponding to each of the lower end and the upper end of the lower portion LMP and the lower end and the upper end of the upper portion UMP of the memory pillar MP is recessed is described, but the embodiment is not limited thereto. For example, the number of conductor layers in which a portion of the boundary with the memory pillar MP is recessed may be two layers for each of the lower end and the upper end of the lower portion LMP and the lower end and the upper end of the upper portion UMP of the memory pillar MP.

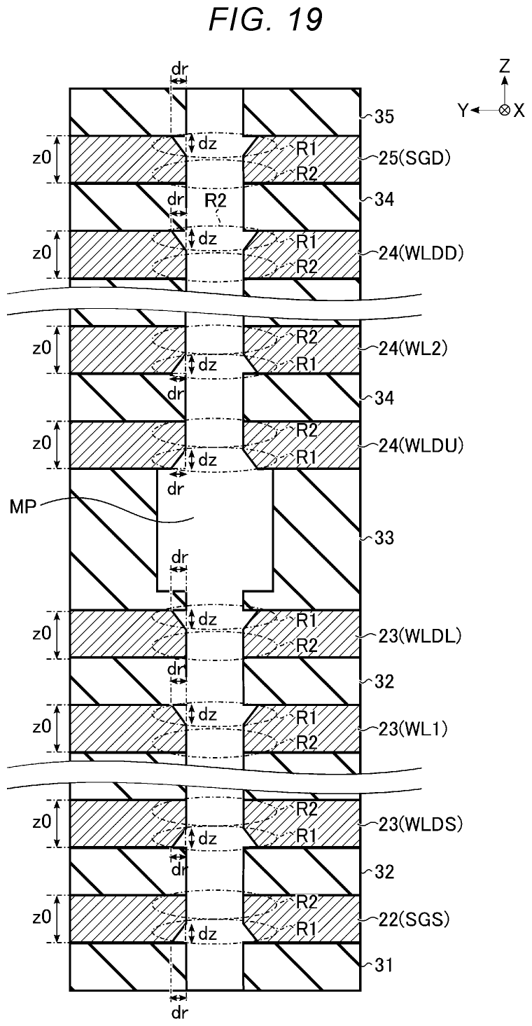

FIG. 19 is a cross-sectional view illustrating an example of a cross-sectional structure in a memory area of a memory device according to a modification. FIG. 19 corresponds to FIG. 7 in the embodiment.

As illustrated in FIG. 19, the memory pillar MP has a portion with a locally larger diameter than the surrounding in the portion intersecting each of the conductor layer 22, the lowermost conductor layer 23, the conductor layer 23 for two layers from the top, the conductor layer 24 for two layers from the bottom, the uppermost conductor layer 24, and the conductor layer 25. In other words, each of the conductor layer 22, the lowermost conductor layer 23, the conductor layer 23 for two layers from the top, the conductor layer 24 for two layers from the bottom, the uppermost conductor layer 24, and the conductor layer 25 may include the recessed portion R1 and the non-recessed portion R2 lined up in the Z direction in the boundary area in contact with the memory pillar MP.

More specifically, the conductor layer 22, the lowermost conductor layer 23, and the conductor layer 24 for two layers from the bottom are recessed toward the lower surface from between the lower surface and the upper surface, and an amount of recession is greatest at the lower surface. The conductor layer 23 for two layers from the top, the uppermost conductor layer 24, and the conductor layer 25 are recessed toward the upper surface from between the lower surface and the upper surface, and the amount of recession is greatest at the upper surface. The maximum value dr of the amount of recession of each of the conductor layer 22, the lowermost conductor layer 23, the conductor layer 23 for two layers from the top, the conductor layer 24 for two layers from the bottom, the uppermost conductor layer 24, and the conductor layer 25 is, for example, 3 nm or more. A thickness dz of the recessed portion R1 of each of the conductor layer 22, the lowermost conductor layer 23, the conductor layer 23 for two layers from the top, the conductor layer 24 for two layers from the bottom, the uppermost conductor layer 24, and the conductor layer 25 is, for example, 7 nm or more and 13 nm or less. The thickness dz of the recessed portion R1 of each of the conductor layer 22, the lowermost conductor layer 23, the conductor layer 23 for two layers from the top, the conductor layer 24 for two layers from the bottom, the uppermost conductor layer 24, and the conductor layer 25 relative to a film thickness z0 (that is, a gate length of the memory cell transistor MT) of each of the conductor layer 22, the lowermost conductor layer 23, the conductor layer 23 for two layers from the top, the conductor layer 24 for two layers from the bottom, the uppermost conductor layer 24, and the conductor layer 25 is, for example, 35% or more and 50% or less.

According to the configuration described above, it is possible to alleviate the electric field concentration that occurs in the conductor layer for two layers at both ends of each of the lower portion LMP and the upper portion UMP of the memory pillar MP. Supplementally, as a countermeasure other than the above-described embodiments for the purpose of alleviating the electric field concentration, there is considered a method for applying a voltage capable of alleviating the electric field concentration in each of the conductor layer 22, the uppermost conductor layer 23, the lowermost conductor layer 24, and the conductor layer 25 during the write operation and the erasing operation. However, when this countermeasure is taken, the location of occurrence of the electric field concentration in the lowermost conductor layer 23, the second conductor layer 23 from the top, the second conductor layer 24 from the bottom, and the uppermost conductor layer 24 can be shifted. In this way, since there is a possibility that the electric field concentration also occurs in the lowermost conductor layer 23, the second conductor layer 23 from the top, the second conductor layer 24 from the bottom, and the uppermost conductor layer 24, it is preferable that the conductor layer also has a shape capable of alleviating the electric field concentration, as in the above-described embodiments.

According to the modification, in the boundary with the memory pillar MP, each of the conductor layer 22, the lowermost conductor layer 23, the conductor layer 23 for two layers from the top, the conductor layer 24 for two layers from the bottom, the uppermost conductor layer 24, and the conductor layer 25 has a shape in which a portion is recessed. Accordingly, even when the location of occurrence of the electric field concentration is shifted from the conductor layer closest to an end portion of the memory pillar MP to the conductor layer secondly closest to the end portion of the memory pillar MP, the electric field concentration can be alleviated. For this reason, it is possible to reduce an unintended increase in the threshold voltage of any one of the conductor layer closest to the end portion of the memory pillar MP and the conductor layer secondly closest to the end portion of the memory pillar MP during the write operation and the erasing operation. Therefore, the reliability of the memory device 3 can be improved.

In addition, in the above-described embodiments, the case where the memory pillar MP is divided into two tiers by one coupling portion JMP is described as the example, but the embodiment is not limited thereto. For example, the memory pillar MP may not be divided by the coupling portion JMP. In this case, the boundary with the memory pillar MP may be recessed for the conductor layers near the upper end and the lower end of the memory pillar MP among the stacked wirings. In addition, for example, the memory pillar MP may be divided into three or more tiers by two or more coupling portions JMP. In this case, the boundary with the memory pillar MP may be recessed for the conductor layers near the upper end and the lower end of each tier of the memory pillar MP among the stacked wirings.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A memory device comprising:
a plurality of insulator layers spaced apart from one another in a first direction;
a plurality of conductor layers spaced apart from one another in the first direction, the plurality of insulator layers and the plurality of insulator layers alternately arranged along the first direction; and
a memory pillar extending in the first direction to intersect the plurality of conductor layers, wherein
the plurality of conductor layers include a first conductor layer having a first portion and a second portion in contact with the memory pillar, wherein
the first portion is recessed relative to the second portion in a second direction intersecting the first direction, and wherein
the plurality of insulator layers include
a first insulator layer provided on a first surface of the first conductor layer closer to the first portion than the second portion, and
a second insulator layer provided on a second surface of the first conductor layer closer to the second portion than the first portion, the second insulator layer being thinner than the first insulator layer in the first direction.

2. The memory device according to claim 1, wherein an amount of recession of the first portion relative to the second portion is equal to or greater than about 3 nm.

3. The memory device according to claim 1, wherein a film thickness of the first portion is equal to or greater than about 7 nm and equal to or less than about 13 nm.

4. The memory device according to claim 1, wherein a ratio of a film thickness of the first portion to a sum of the film thickness of the first portion and a film thickness of the second portion is equal to or greater than 35% and equal to or less than 50%.

5. The memory device according to claim 1, wherein
the first conductor layer is a lowermost conductor layer among the plurality of conductor layers, and
the first portion is located below the second portion.

6. The memory device according to claim 5, wherein a portion of the memory pillar intersecting the first conductor layer functions as a select transistor.

7. The memory device according to claim 1, wherein
the first conductor layer is an uppermost conductor layer among the plurality of conductor layers, and
the first portion is located above the second portion.

8. The memory device according to claim 7, wherein a portion of the memory pillar intersecting the first conductor layer functions as a select transistor.

9. The memory device according to claim 1, wherein
the memory pillar includes a lower portion, an upper portion located above the lower portion, and a coupling portion coupling between the lower portion and the upper portion, and
side surfaces of the coupling portion are deviated from extensions of respective side surfaces of the lower portion and the upper portion.

10. The memory device according to claim 9, wherein
the first conductor layer is a lowermost conductor layer intersecting the upper portion of the memory pillar among the plurality of conductor layers, and
the first portion is located below the second portion.

11. The memory device according to claim 10, wherein a portion of the memory pillar intersecting the first conductor layer functions as a dummy cell.

12. The memory device according to claim 9, wherein
the first conductor layer is an uppermost conductor layer intersecting the lower portion of the memory pillar among the plurality of conductor layers, and
the first portion is located above the second portion.

13. The memory device according to claim 12, wherein a portion of the memory pillar intersecting the first conductor layer functions as a dummy cell.

14. The memory device according to claim 1, wherein
the plurality of conductor layers further include a second conductor layer provided on a surface of the second insulator layer opposite to a surface on which the first conductor layer is provided, wherein
the second conductor layer includes a third portion and a fourth portion in contact with the memory pillar, wherein
the third portion is recessed relative to the fourth portion in the second direction.

15. The memory device according to claim 14, wherein an amount of recession of the third portion relative to the fourth portion is equal to or greater than about 3 nm.

16. The memory device according to claim 14, wherein a film thickness of the third portion is equal to or greater than about 7 nm and equal to or less than about 13 nm.

17. The memory device according to claim 14, wherein a ratio of a film thickness of the third portion to a sum of the film thickness of the third portion and a film thickness of the fourth portion is equal to or greater than about 35% and equal to or less than about 50%.

18. The memory device according to claim 14, wherein the third portion is located above the fourth portion when the first portion is located above the second portion, and is located below the fourth portion when the first portion is located below the second portion.

19. The memory device according to claim 18, wherein
the plurality of insulator layers further include a third insulator layer provided on a surface of the second conductor layer closer to the fourth portion than the second portion, and
a film thickness of the third insulator layer is substantially equal to a film thickness of the second insulator layer.

20. The memory device according to claim 1, wherein a diameter of a portion of the memory pillar intersecting the first portion is larger than a diameter of a portion of the memory pillar intersecting the second portion.
